(19) United States
(12) Patent Application Publication
(10) Pub. No.: US 2007/0103174 A1
(43) Pub. Date: May 10, 2007

(54) Direct current test apparatus

(75) Inventor: Hironori Tanaka, Tokyo (JP)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 11/589,687

(22) Filed: Oct. 30, 2006

Related U.S. Application Data
(63) Continuation of application No. PCT/JP05/07912, filed on Apr. 26, 2005.

(30) Foreign Application Priority Data
Apr. 28, 2004 (JP) 2004-133955

(51) Int. Cl. G01R 27/08

(52) U.S. Cl. 324/720

(57) ABSTRACT

There is provided a DC test apparatus for performing a test by applying a DC voltage and a DC current to an electronic device. The DC test apparatus includes a power supply generating section that generates the DC voltage and the DC current, a current detecting resistance provided in series between the power supply generating section and the electronic device, and a current detecting section that detects a level of the DC current based on a difference in potential between ends of the current detecting resistance. The current detecting section includes a reference resistance that has a smaller temperature coefficient than the current detecting resistance, and a temperature compensating section that detects the level of the DC current by multiplying the difference in potential between the ends of the current detecting resistance with a coefficient determined in accordance with a ratio between a resistance value of the current detecting resistance and a resistance value of the reference resistance.

### CROSS REFERENCE TO RELATED APPLICATIONS

This patent application incorporates herein by reference the contents of a Japanese Patent Application No. 2004-133955 filed on Apr. 28, 2004, if applicable.

### BACKGROUND

1. Field of the Invention

The present invention relates to a direct current (DC) test apparatus for performing a DC test on an electronic device. This patent application incorporates herein by reference the contents of a Japanese Patent Application No. 2004-133955 filed on Apr. 28, 2004, if applicable.

2. Related Art

Typical test methods used for testing electronic devices such as semiconductor circuits include direct current (DC) tests. Examples of the DC tests are a voltage-application current-measurement test in which a predetermined DC voltage is applied to an electronic device, and a DC voltage supplied to the electronic device as a result of the voltage application is measured, and a current-application voltage-measurement test in which a predetermined DC current is applied to an electronic device, and a DC voltage supplied to the electronic device as a result of the current application is measured.

FIG. 1 shows the construction of a typical DC test apparatus 200. The DC test apparatus 200 performs a voltage-application current-measurement test on an electronic device 300. The DC test apparatus 200 includes therein a power supply 202, an amplifier 210, a plurality of current detecting resistances (206-1 to 206-n, n is an integer of 2 or more), an amplifier 212, and an analog to digital converter (ADC) 204. The power supply 202 generates a predetermined voltage. The amplifier 210 amplifies the voltage generated by the power supply 202, and outputs the amplified voltage. The plurality of current detecting resistances 206 respectively provide the same resistance, and are connected in parallel with each other between the amplifier 210 and the electronic device 300.

The voltage applied to the electronic device 300 is fed back into the amplifier 210 so that the amplifier 210 generates a predetermined DC voltage. Here, the amplifier 212 outputs a voltage determined in accordance with a difference in potential between the ends of the current detecting resistances 206, and the ADC 204 measures a DC current supplied to the electronic device 300 on the basis of the voltage output from the amplifier 212.

Since no patent and other documents related to the present invention have been found, recitation of such documents will be omitted.

In the typical DC test apparatus 200, the amplifiers 210 and 212 are formed on the same semiconductor chip 208, and the current detecting resistances 206 are formed outside the semiconductor chip 208. This design results in the DC test apparatus 200 of large size for the following reason. To make the measurement range for the DC current variable, it is required to provide switches to connect/disconnect the plurality of current detecting resistances 206 and to vary the measurement range by switching the respective switches. Therefore, the typical DC test apparatus 200 needs a large circuit separately from the semiconductor chip 208.

In addition, the current detecting resistances 206 need to be fabricated by using the wafer fabrication process in order to be formed on the semiconductor chip 208. However, the wafer fabrication process has difficulties in forming resistances of small temperature coefficient. Consequently, the resistance value of the current detecting resistances 206 is affected to vary by the change in temperature of the semiconductor chip 208. This reduces the accuracy in measuring the current.

### SUMMARY

An advantage of some aspects of the present invention is to provide a test apparatus that can solve the above-stated problems. This is achieved by combining the features recited in the independent claims. The dependent claims define further effective specific example of the present invention.

A first embodiment of the present invention provides a DC test apparatus for performing a test by applying a DC voltage and a DC current to an electronic device. The DC test apparatus includes a power supply generating section that generates the DC voltage and the DC current, a current detecting resistance provided in series between the power supply generating section and the electronic device, and a current detecting section that detects a level of the DC current based on a difference in potential between ends of the current detecting resistance. Here, the current detecting section includes a reference resistance that has a smaller temperature coefficient than the current detecting resistance, and a temperature compensating section that detects the level of the DC current by multiplying the difference in potential between the ends of the current detecting resistance with a coefficient determined in accordance with a ratio between a resistance value of the current detecting resistance and a resistance value of the reference resistance.

The temperature compensating section may have a current detecting amplifier that outputs a voltage determined in accordance with the difference in potential between the ends of the current detecting resistance, an artificial resistance connected in series to an output end of the current detecting amplifier, where the artificial resistance has substantially the same temperature coefficient as the current detecting resistance, and a temperature compensating amplifier that amplifies the voltage output from the current detecting amplifier at an amplification rate determined in accordance with a ratio between a resistance value of the artificial resistance and the resistance value of the reference resistance, and outputs the amplified voltage.

A plurality of the current detecting resistances may be provided in parallel with each other between the power supply generating section and the electronic device. It is preferable that the power supply generating section, the current detecting resistance, the current detecting amplifier, the artificial resistance, and the temperature compensating amplifier are formed on the same semiconductor chip, and that the reference resistance is formed outside the semiconductor chip. The current detecting resistance and the artificial resistance may be formed by the same wafer fabrication process.

The temperature compensating amplifier may be a differential amplifier, and a positive input terminal of the temperature compensating amplifier may be grounded. The artificial resistance may be provided in series between a negative input terminal of the temperature compensating amplifier and an output terminal of the current detecting amplifier. The reference resistance may be provided in series between an output terminal and the negative input terminal of the temperature compensating amplifier.

The DC test apparatus may further include a feedback section that feeds back a voltage applied to the electronic device into the power supply generating section and controls the DC voltage generated by the power supply generating section to be a predetermined voltage, and a measuring section that measures the DC current based on the voltage output from the temperature compensating amplifier. The power supply generating section may control the DC current to be a predetermined current based on the voltage output from the temperature compensating section, and the DC test apparatus may further include a measuring section that measures a voltage applied to the electronic device.

Here, all the necessary features of the present invention are not listed in the summary of the invention. The sub-combinations of the features may also become the invention.

### BRIEF DESCRIPTION OF THE DRAWINGS

FIG. 1 shows the construction of the typical DC test apparatus 200.

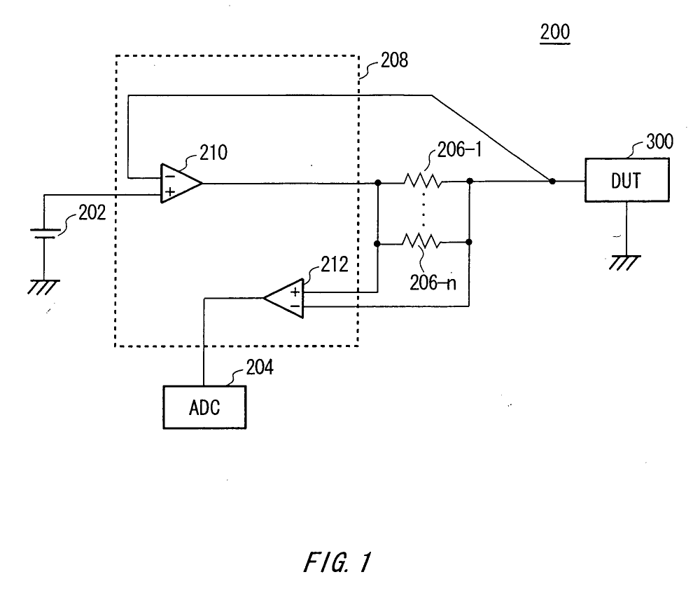

FIG. 2 shows an example of the construction of a DC test apparatus 100 relating to an embodiment of the present invention.

FIG. 3 shows another example of the construction of the DC test apparatus 100.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

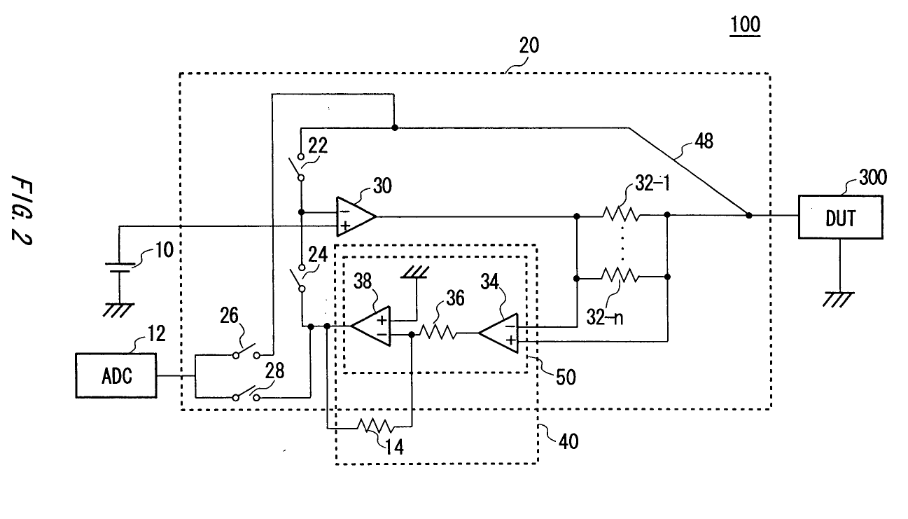

FIG. 2 shows an example of the construction of a DC test apparatus 100 relating to an embodiment of the present invention. The DC test apparatus 100 performs a test by applying a DC voltage and a DC current to an electronic device 300 which is, for example, a semiconductor device. The DC test apparatus 100 includes therein a power supply 10, an analog to digital converter (ADC) 12, a plurality of switches (22, 24, 26 and 28), a power supply generating section 30, a plurality of current detecting resistances (32-1 to 32-n, n is an integer of 2 or more), a current detecting section 40, and a feedback line 48.

The following first briefly describes operations of the test apparatus 100 for performing a voltage-application current-measurement test, where a predetermined DC voltage is applied to the electronic device 300, and a DC current supplied to the electronic device 300 as a result of the voltage application is measured. When the test apparatus 100 conducts this type of test, the switches 22 and 28 are short-circuited, and the switches 24 and 26 are opened.

The power supply 10 generates a predetermined voltage, and the power supply generating section 30 generates a DC voltage determined in accordance with the voltage applied by the power supply 10. Here, each of the plurality of current detecting resistances 32 is provided in series with the output terminal of the power supply generating section 30 and the input terminal of the electronic device 300 so as to be positioned therebetween. In other words, the current detecting resistances 32 are provided in parallel with each other so as to be positioned between the power supply generating section 30 and the electronic device 300.

The feedback line 48 feeds back the voltage applied to the electronic device 300 into the power supply generating section 30 via the switch 22 so that the power supply generating section 30 generates a predetermined DC voltage. Which is to say, the feedback line 48 and switch 22 together function as a feedback section in the embodiment of the present invention. The power supply generating section 30 is a differential amplifier, for example, and receives the voltage generated by the power supply 10 at its positive input terminal and the voltage fed back by the feedback section at its negative input terminal. Based on such a configuration, the power supply generating section 30 applies a predetermined DC voltage to the electronic device 300.

The current detecting section 40 detects the level of the DC current supplied to the electronic device 300 on the basis of the difference in potential between the ends of the current detecting resistances 32. To be specific, according to the present embodiment, the current detecting section 40 detects the current flowing one current detecting resistance 32 on the basis of the potential difference. Then, the current detecting section 40 multiplies the detected current with the number of the current detecting resistances 32 connected in parallel, so as to measure the DC current supplied to the electronic device 300. Here, the test apparatus 100 may additionally include therein switches to vary the number of the current detecting resistances 32 connected in parallel. If such is the case, the test apparatus 100 can alter the measurement range for the DC current by setting the number of the current detecting resistances 32 connected in parallel at different values.

The ADC 12 receives, via the switch 28, a voltage which the current detecting section 40 outputs in accordance with the detected current, and measures the DC current supplied to the electronic device 300 by analog-to-digital converting the voltage. In other words, the ADC 12 functions as a measuring section for measuring the DC current on the basis of the voltage output from a temperature compensating amplifier 38.

The following briefly describes operations of the test apparatus 100 for performing a current-application voltage-measurement test, where a predetermined DC current is applied to the electronic device 300, and a DC voltage supplied to the electronic device 300 as a result of the current application is measured. When the test apparatus 100 conducts this type of test, the switches 22 and 28 are opened, and the switches 24 and 26 are short-circuited.

The power supply 10 generates a predetermined voltage, and the power supply generating section 30 generates a DC current determined in accordance with the voltage applied by the power supply 10. Here, the power supply generating section 30 is supplied, at its negative input terminal, with a voltage determined in accordance with the current detected by the current detecting section 40. With such a configuration, the power supply generating section 30 can supply a predetermined DC current to the electronic device 300. The ADC 12 analog-to-digital converts the voltage that is applied to the electronic device 300 as a result of the application of the predetermined DC current to the electronic device 300, so as to measure the DC voltage. In other words, the ADC 12 functions as a measuring section for measuring the DC voltage applied to the electronic device 300.

The following explains the construction of the current detecting section 40. The current detecting section 40 includes therein a temperature compensating section 50 and a reference resistance 14. The reference resistance 14 has a smaller temperature coefficient than the current detecting resistances 32. Which is to say, the reference resistance 14 exhibits a smaller change in resistance value when the surrounding temperature changes, when compared to the current detecting resistances 32.

The temperature compensating section 50 detects the level of the DC current supplied to the electronic device 300 by multiplying the difference in potential between the ends of the current detecting resistances 32 with a coefficient determined in accordance with the ratio between the resistance value of the current detecting resistances 32 and the resistance value of the reference resistance 14. For example, the temperature compensating section 50 multiplies the potential difference between the ends of the current detecting resistances 32 with a coefficient obtained by dividing the resistance value of the reference resistance 14 by the resistance value of the current detecting resistances 32. In this manner, the temperature compensating section 50 can prevent the degradation in the current detecting accuracy which results from a change in the resistance value of the current detecting resistances 32 caused by a change in the surrounding temperature.

According to the present embodiment, the temperature compensating section 50 includes therein a current detecting amplifier 34, an artificial resistance 36, and a temperature compensating amplifier 38. The current detecting amplifier 34 outputs a voltage determined in accordance with the potential difference between the ends of the current detecting resistances 32. The artificial resistance 36 is connected in series to the output end of the current detecting amplifier 34. Here, the artificial resistance 36 has substantially the same temperature coefficient as the current detecting resistances 32.

The temperature compensating amplifier 38 amplifies the voltage output from the current detecting amplifier 34 at an amplification rate determined in accordance with the ratio between the resistance value of the artificial resistance 36 and the resistance value of the reference resistance 14, and outputs the amplified voltage. Here, the temperature compensating amplifier 38 is a differential amplifier, for example, and its positive input terminal is grounded. The artificial resistance 36 is connected in series between the negative input terminal of the temperature compensating amplifier 38 and the output terminal of the current detecting amplifier 34. The reference resistance 14 is provided in series between the output terminal and the negative input terminal of the temperature compensating amplifier 38.

Here, it is preferable that the power supply generating section 30, current detecting resistances 32, current detecting amplifier 34, artificial resistance 36, temperature compensating amplifier 38, switches 22, 24, 26 and 28, and feedback line 48 are formed on the same semiconductor chip 20, and that the reference resistance 14 is formed outside the semiconductor chip 20. Being provided outside the semiconductor chip 20, the reference resistance 14 which has a small temperature coefficient can be formed easily. In addition, despite the provision of the plurality of current detecting resistances 32, the test apparatus 100 can perform temperature compensation with it being possible to achieve small circuit scale. This is because temperature compensation can be made possible by providing one reference resistance 14 outside the semiconductor chip 20.

The current detecting resistances 32 and artificial resistance 36 can be formed by the same wafer fabrication process. Being manufactured by the same wafer fabrication process, the current detecting resistances 32 and artificial resistance 36 can be easily configured to have substantially the same characteristics. Here, the artificial resistance 36 is preferably located in the vicinity of the current detecting resistances 32.

As described above, when the resistance value of the current detecting resistances 32 changes due to the change in temperature, the current detecting section 40 relating to the present embodiment can compensate the change in the resistance value, thereby enabling highly accurate current detection. Because of this advantage, the current detecting section 40 can accurately measure the DC current when performing a voltage-application current-measurement test, and can accurately generate the DC current when performing a current-application voltage-measurement test.

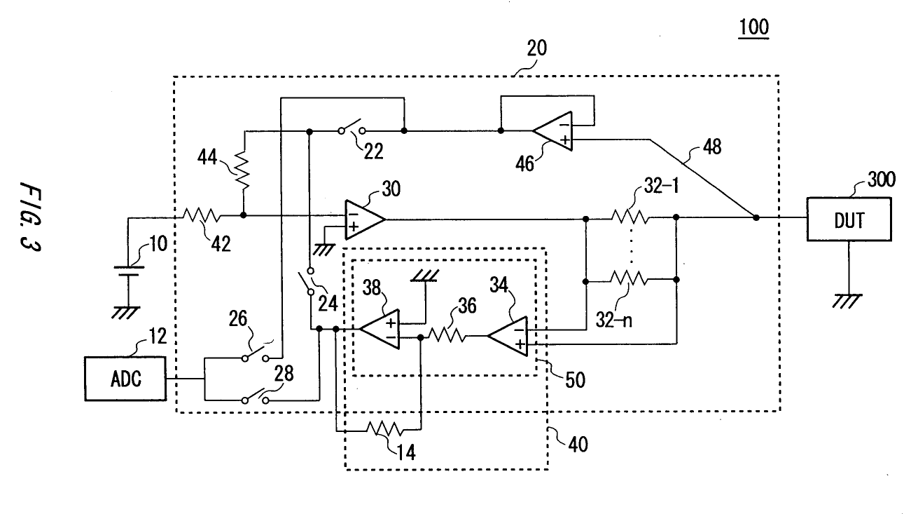

FIG. 3 shows another example of the construction of the DC test apparatus 100. The DC test apparatus 100 relating to this embodiment includes therein resistances 42 and 44, and an amplifier 46 in addition to the constituents of the DC test apparatus 100 relating to the previous embodiment illustrated with reference to FIG. 2. The power supply generating section 30 relating to the present embodiment is an inverting differential amplifier. The negative input terminal of the power supply generating section 30 receives the voltage generated by the power supply 10 via the resistance 42, and the positive input terminal is grounded.

When the DC test apparatus 100 performs a voltage-application current-measurement test, the feedback line 48 feeds back the DC voltage into the negative input terminal of the power supply generating section 30 via the amplifier 46, switch 22, and resistance 44. When the DC test apparatus 100 performs a current-application voltage-measurement test, the current detecting section 40 feeds back the DC current into the negative input terminal of the power supply generating section 30 via the switch 24 and resistance 44.

The DC test apparatus 100 having the above-described construction can also perform temperature compensation with it being possible to achieve a small circuit scale, similarly to the DC test apparatus 100 illustrated with reference to FIG. 2.

While the embodiments of the present invention have been described, the technical scope of the invention is not limited to the above described embodiments. It is apparent to persons skilled in the art that various alternations and improvements can be added to the above-described embodiments. It is also apparent from the scope of the claims that the embodiments added with such alternations or improvements can be included in the technical scope of the invention.

As clearly indicated above, some embodiments of the present invention can provide a DC test apparatus of small circuit scale which can perform temperature compensation for current detection accuracy.

What is claimed is:

1. A DC test apparatus for performing a test by applying a DC voltage and a DC current to an electronic device, the DC test apparatus comprising:
a power supply generating section that generates the DC voltage and the DC current;
a current detecting resistance provided in series between the power supply generating section and the electronic device; and
a current detecting section that detects a level of the DC current based on a difference in potential between ends of the current detecting resistance, the current detecting section including:
a reference resistance that has a smaller temperature coefficient than the current detecting resistance; and
a temperature compensating section that detects the level of the DC current by multiplying the difference in potential between the ends of the current detecting resistance with a coefficient determined in accordance with a ratio between a resistance value of the current detecting resistance and a resistance value of the reference resistance.

2. The DC test apparatus as set forth in claim 1, wherein
the temperature compensating section has:
a current detecting amplifier that outputs a voltage determined in accordance with the difference in potential between the ends of the current detecting resistance;
an artificial resistance connected in series to an output end of the current detecting amplifier, the artificial resistance having substantially a same temperature coefficient as the current detecting resistance; and
a temperature compensating amplifier that amplifies the voltage output from the current detecting amplifier at an amplification rate determined in accordance with a ratio between a resistance value of the artificial resistance and the resistance value of the reference resistance, and outputs the amplified voltage.

3. The DC test apparatus as set forth in claim 2, wherein
a plurality of the current detecting resistances are provided in parallel with each other between the power supply generating section and the electronic device.

4. The DC test apparatus as set forth in claim 2, wherein
the power supply generating section, the current detecting resistance, the current detecting amplifier, the artificial resistance, and the temperature compensating amplifier are formed on a same semiconductor chip, and
the reference resistance is formed outside the semiconductor chip.

5. The DC test apparatus as set forth in claim 4, wherein
the current detecting resistance and the artificial resistance are formed by a same wafer fabrication process.

6. The DC test apparatus as set forth in claim 4, wherein
the temperature compensating amplifier is a differential amplifier, and a positive input terminal of the temperature compensating amplifier is grounded,
the artificial resistance is provided in series between a negative input terminal of the temperature compensating amplifier and the output terminal of the current detecting amplifier, and
the reference resistance is provided in series between an output terminal and the negative input terminal of the temperature compensating amplifier.

7. The DC test apparatus as set forth in claim 6, further comprising:
a feedback section that feeds back a voltage applied to the electronic device into the power supply generating section, and controls the DC voltage generated by the power supply generating section to be a predetermined voltage; and
a measuring section that measures the DC current based on the voltage output from the temperature compensating amplifier.

8. The DC test apparatus as set forth in claim 6, wherein
the power supply generating section controls the DC current to be a predetermined current based on the voltage output from the temperature compensating section, and
the DC test apparatus further comprises a measuring section that measures a voltage applied to the electronic device.
